(19) United States
(12) Patent Application Publication
(10) Pub. No.: US 2026/0107793 A1
(43) Pub. Date: Apr. 16, 2026

(54) THREE-DIMENSIONAL SYSTEM-ON-CHIP DEVICE

(71) Applicant: Thinchipway CO., LTD., Zhubei City (TW)

(72) Inventor: Tzu-Wei CHIU, Zhubei City (TW)

(21) Appl. No.: 19/277,035

(22) Filed: Jul. 22, 2025

(30) Foreign Application Priority Data
Oct. 11, 2024 (TW) 113138712

(51) Int. Cl. H01L 23/538; H01L 23/00; H01L 23/31; H01L 23/498; H01L 25/065; H01L 25/16; H01L 25/18; H10B 80/00; H10D 80/30

(52) U.S. Cl. CPC H10W 70/611; H10D 80/30; H10W 70/65; H10W 90/401; H10B 80/00; H10W 72/221; H10W 74/114; H10W 80/312; H10W 80/327; H10W 90/00; H10W 90/724; H10W 90/794

(57) ABSTRACT

A 3D SoC device includes an intermediate redistribution layer, a lower semiconductor module, and an upper semiconductor module. The intermediate redistribution layer electrically connects the lower semiconductor module to the upper semiconductor module and further connects to an external power source. The lower semiconductor module includes a lower dielectric layer, a lower insulating layer, a plurality of lower conductive posts, a lower chip unit, and a plurality of solder balls. The lower chip unit is composed of a plurality of SoC processing chips located in the lower dielectric layer. The upper semiconductor module includes an upper dielectric layer, and a plurality of upper layer chips.

### CROSS-REFERENCE TO RELATED APPLICATION

This application claims priority to Taiwanese Invention Patent Application No. 113138712, filed on Oct. 11, 2024, and incorporated by reference herein in its entirety.

### FIELD

The disclosure relates to a system-on-chip (SoC) device, and more particularly to a three-dimensional (3D) SoC device.

### BACKGROUND

Referring to FIG. 1, a conventional face-to-face (F2F) packaged three dimensional (3D) system on chip (SoC) structure 1 includes a redistribution layer 11, a plurality of solder balls 12 attached below the redistribution layer 11, a lower chip module 13 stacked on the redistribution layer 11, and an upper chip module 14 stacked above the lower chip module 13. The lower chip module 13 includes a lower encapsulation layer 131 located above the redistribution layer 11, two lower memory chips 132 that are embedded in and spaced apart by the lower encapsulation layer 131, and a lower processor chip 133 that is embedded in the lower encapsulation layer 131 and that is located between the two lower memory chips 132. The upper chip module 14 includes an upper encapsulating layer 141, two upper processing chips 142 that are embedded in and spaced apart by the upper encapsulating layer 141, and an upper memory chip 143 that is embedded in the upper encapsulating layer 141 and located between the two upper processing chips 142. The lower chip module 13 and the upper chip module 14 are packaged face-to-face (F2F). Additionally, the lower chip module 13 further includes two copper posts 134 that each passes through the lower encapsulation layer 131, that are located near two opposite sides of the lower encapsulation layer 131, and that are both electrically connected to the redistribution layer 11 and the upper processing chips 142 of the upper chip module 14.

In the conventional 3D SoC structure 1, the F2F packaging vertically integrates the upper and lower chip modules 13, 14 into a single packaged structure to occupy a single space on a PCB. The vertically stacking of the upper and lower chip modules provides several benefits such as enhanced processing capabilities, space efficiency, energy efficiency, etc. Therefore, it is desirable for the advanced semiconductor packaging industry to continually improve processing technologies for 3D SoC designs and systems.

### SUMMARY

Therefore, an object of the disclosure is to provide a three-dimensional (3D) system-on-chip (SoC) device that can alleviate at least one of the drawbacks of the prior art.

According to the disclosure, the 3D SoC device includes an intermediate redistribution layer, a lower semiconductor module, and an upper semiconductor module. The intermediate redistribution layer has a top surface and a bottom surface. The lower semiconductor module is located on the bottom surface of the intermediate redistribution layer. The upper semiconductor module is located on the top surface of the intermediate redistribution layer. The intermediate redistribution layer electrically connects the lower semiconductor module to the upper semiconductor module and further connects to an external power source. The lower semiconductor module includes a lower dielectric layer, a lower insulating layer, a plurality of lower conductive posts, and a lower chip unit. The lower dielectric layer is located on the bottom surface of the intermediate redistribution layer. The lower insulating layer is located on a surface of the lower dielectric layer remote from the intermediate redistribution layer, and includes a plurality of openings spaced apart from each other. The lower conductive posts pass through the lower dielectric layer, and respectively correspond in position to some of the openings. Each of the lower conductive posts have an end that is exposed form the corresponding one of the openings, and another end that is electrically connected with the intermediate redistribution layer. The lower chip unit is composed of a plurality of SoC processing chips, and located in the lower dielectric layer. Each of the SoC processing chips is located between adjacent ones of the lower conductive posts. Each of the SoC processing chips includes a first processor redistribution layer, a first processor substrate, a processor active layer, a second processor redistribution layer, a processor dielectric layer, a second processor substrate, a plurality of first vias. The first processor redistribution layer has a plurality of electrode pads exposed from the openings. The first processor substrate is disposed on the first processor redistribution layer and has a plurality of second vias formed through the first processor substrate. The processor active layer is formed on the first processor redistribution layer and is connected to the first processor redistribution layer through the first vias. The second processor redistribution layer is disposed on and electrically connected to the processor active layer. The processor dielectric layer is disposed on and connected to the second processor redistribution layer. The second processor substrate is disposed on and connected to the processor dielectric layer. The second vias pass through the processor dielectric layer and the second processor substrate, and each of the second vias electrically connects with the second processor redistribution layer and the intermediate redistribution layer. The lower semiconductor module further includes a plurality of solder balls which are respectively disposed in the openings for electrical connection with the electrode pads of the processor chip and the lower conductive posts. The upper semiconductor module includes an upper dielectric layer, and a plurality of upper layer chips. The upper dielectric layer is located on the upper surface of the intermediate redistribution layer. The upper layer chips are embedded in the upper dielectric layer in a spaced apart manner. Each of the upper layer chips has an upper redistribution layer electrically connected to the intermediate redistribution layer, an upper active layer stacked on and electrically connected to the upper redistribution layer, and an upper substrate stacked on the upper active layer.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a schematic cross-sectional view illustrating a conventional face-to-face packaged three dimensional (3D) system on chip (SoC) structure.

FIG. 2 is a schematic cross-sectional view illustrating a first embodiment of a 3D SoC device according to the present disclosure.

FIG. 3A is a schematic cross-sectional view illustrating source power/ground connection pathways of the first embodiment.

FIG. 3B is a schematic cross-sectional view illustrating signal connection pathways of the first embodiment.

FIGS. 4A to 4C illustrate a second embodiment according to the present disclosure.

FIG. 5 is a schematic cross-sectional view illustrating a third embodiment according to the present disclosure.

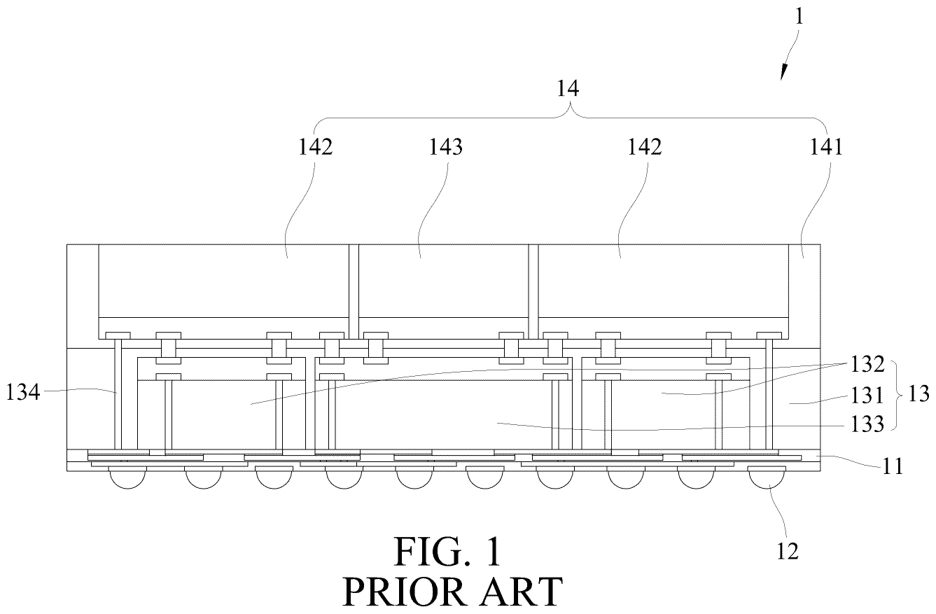

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

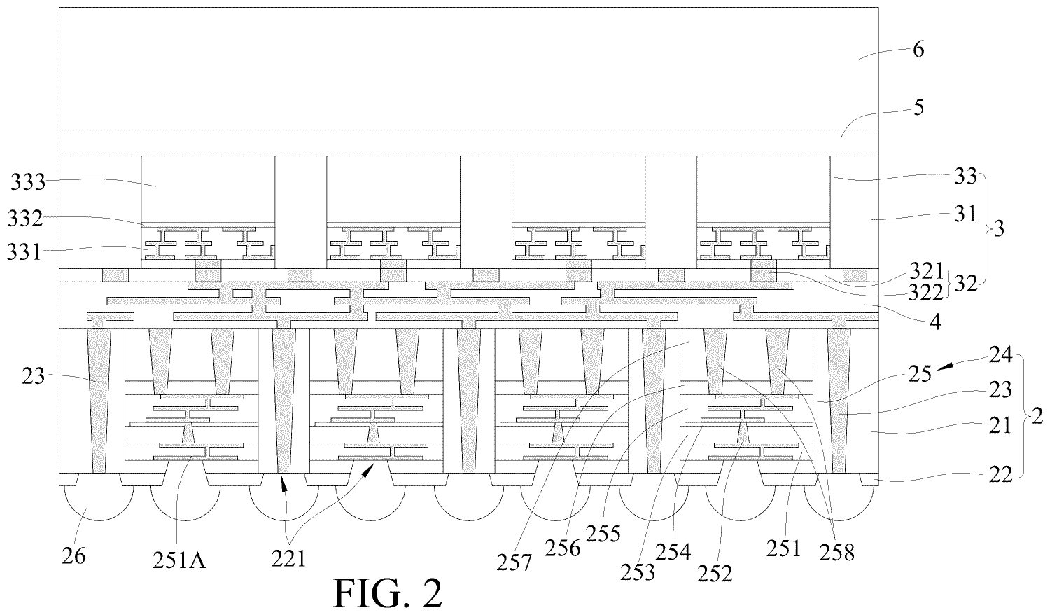

Referring to FIG. 2, a first embodiment of a three-dimensional (3D) system-on-chip (SoC) device includes an intermediate redistribution layer 4, a lower semiconductor module 2, and an upper semiconductor module 3. The intermediate redistribution layer 4 has a top surface and a bottom surface. The lower semiconductor module 2 is located on the bottom surface of the intermediate redistribution layer 4. The upper semiconductor module 3 is located on the top surface of the intermediate redistribution layer 4.

The intermediate redistribution layer 4 electrically connects the lower semiconductor module 2 to the upper semiconductor module 3 and further connects to an external power source.

The lower semiconductor module 2 includes a lower dielectric layer 21, a lower insulating layer 22, a plurality of lower conductive posts 23, a lower chip unit 24, and a plurality of solder balls 26. The lower dielectric layer 21 is located on the bottom surface of the intermediate redistribution layer 4. The lower insulating layer 22 is located on a surface of the dielectric layer 21 remote from the intermediate redistribution layer 4, and includes a plurality of openings 221 that are spaced apart from each other. The plurality of lower conductive posts 23 passes through the lower dielectric layer 21, and respectively correspond in position to some of the openings 221. The lower chip unit 24 is located in the lower dielectric layer 21. In this embodiment, the lower insulating layer 22 and the lower dielectric layer 21 are made of dielectric materials such as Si₃N₄, SiO₂, SiON, SiN etc.

Each of the lower conductive posts 23 has an end that is exposed from the corresponding one of the openings 221 and that is connected with a solder ball 26, and another end that is electrically connected with the intermediate redistribution layer 4. Additionally, the lower conductive posts 23 may have a width that substantially approaches 10 μm, and a height that is substantially approaches 30 μm. When the 3D SoC device according to the present disclosure is in operation signals may be sent to the upper semiconductor module 3 via the lower conductive posts 23 and the intermediate redistribution layer 4.

The lower chip unit 24 is composed of a plurality of SoC processing chips 25 that are advanced logic nodes and are 7 nm and below chips fabricated with 7 nm or even lower processing technology. This means that the SoC processing chips 25 are high end processing chips and exclude other types of SoCs such as memory chips, input/output (I/O) chips, passive component chips, and low end processing chips. By fabricating the SoC processing chips 25 with 7 nm/below technology, and by excluding memory chips, I/O chips, passive components and low end processing chips from the lower chip unit 24, the SoC processing chips 25 may be concentrated in the lower chip unit 24, thereby increasing the transistor count and the overall processing power of the lower chip unit 24.

Each of the SoC processing chips 25 is located between adjacent ones of the lower conductive posts 23. Each of the SoC processing chips 25 includes a first processor redistribution layer 251, a first processor substrate 253, a processor active layer 254, a second processor redistribution layer 255, a processor dielectric layer 256, a second processor substrate 257, and a plurality of second vias 258. The first processor redistribution layer 251 of each SoC processing chip 25 has a plurality of interconnects 251A (only one is shown per SoC processing chip 25) exposed from the openings 221. The first processor substrate 253 of each SoC processing chip 25 is disposed on the first processor redistribution layer 251 and has a plurality of first vias 252 (only one first via 252 is shown per SoC processing chip 25 in the Figures) formed through the first processor substrate 253. The processor active layer 254 of each SoC processing chip 25 is formed on the first processor substrate 253 and connected to the first processor redistribution layer 251 through the first vias 252. The second processor redistribution layer 255 is disposed on and electrically connected to the processor active layer 254. The processor dielectric layer 256 is disposed on and connected to the second processor redistribution layer 255. The second processor substrate 257 is disposed on and connected to the processor dielectric layer 256. The plurality of second vias 258 pass through the processor dielectric layer 256 and the second processor substrate 257 and each electrically connect with the second processor redistribution layer 255 and the intermediate redistribution layer 4. The solder balls 26 of the lower semiconductor module 2 are respectively disposed in the openings 221 for electrical connection with the interconnects 251A of the SoC processing chips 25 and the lower conductive posts 23. It should be noted that the first vias 252 and the second vias 258 of the SoC processing chips 25 each may have a conductive filling such as copper. Therefore the first vias 252 and the second vias 258 may be used to transfer electrical signals or to form electrical connections. Additionally, each of the first vias 252 in the first processor substrate 253 of the SoC processing chips 25 of the lower semiconductor module 2 has a diameter ranging from 100 nm to 500 nm. The second vias 258 of each of the SoC processing chips 25 of the lower semiconductor module 2 have a diameter that substantially approaches 2 μm and a height that substantially approaches 10 μm. When the 3D SoC device of the present disclosure is in operation, transmission signals may be sent to the upper semiconductor module 3 via the second vias 258 and the intermediate redistribution layer 4.

It is noted that the solder balls 26 respectively correspond in position to the openings 221. The solder balls 26 are respectively electrically connected to the interconnects 251A of the SoC processing chips 25 exposed from the respective openings 221. The rest of the solder balls 26 are respectively electrically connected to the lower conductive posts 23 exposed from the respective openings 22. The solder balls 26 allow the 3D SoC device to be electrically connected with other electrical components.

In this embodiment, each of the SoC processing chips 25 of the lower chip unit 24 are high end processors fabricated with 7nm/below technology. The first processor substrate 253 of each of the SoC processing chips 25 has a thickness that is less than 0.5 μm. Each of the SoC processing chips 25 of the lower chip unit 24 has a thickness that ranges from 10 μm to 200 μm. Each of the solder balls 26 of the lower semiconductor module 2 has a thickness that ranges from 10 μm to 150 μm. The solder balls 26 are spaced apart from each other by a distance that ranges from 20 μm to 200 μm. In this embodiment, when the 3D SoC device is under operation, the first vias 252 of the first processor substrate 253 of each of the SoC processing chips 25 allow electrical connection to a source voltage (Vss) or a drain voltage (Vdd) via a backside of the first processor substrate 253 opposite to the processor active layer 254.

It should be noted that a method for fabricating the SoC processing chips 25 of the present disclosure is more or less similar to the one disclosed in Taiwanese Invention Patent No. TWI779617.

The upper semiconductor module 3 includes an upper dielectric layer 31, a hybrid bonding layer 32, and a plurality of upper layer chips 33. The upper dielectric layer 31 is located on the upper surface of the intermediate redistribution layer 4. The hybrid bonding layer 32 is located in a bottom portion of the dielectric layer 31 (in a side that is close to the intermediate redistribution layer 4). The upper layer chips 33 are embedded in the upper dielectric layer 31 in a spaced apart manner.

The upper dielectric layer 31 is similar to the lower dielectric layer 21 and further description thereof is omitted for the sake of brevity.

The hybrid bonding layer 32 has a dielectric material layer 321, and a plurality of conducting pads 322 that are embedded in the dielectric material layer 321 that provides electrically conduction between the intermediate redistribution layer 4 and the upper layer chips 33. More specifically, the upper conducting pads 322 are distributed in a spaced apart manner in the dielectric material layer 321 with a pitch (pitch distance) between adjacent upper conducting pads 322 that may range from 1 μm to 9 μm. In some of the upper conducting pads 322, one side of these upper conducting pads 322 is connected to an upper layer chip 33, while another side thereof is connected to the intermediate redistribution layer 4. The hybrid bonding layer 32 allows metal contacts to be embedded in a bottom side of the upper dielectric layer 31. After a heat treatment, the hybrid bonding layer 32 is bonded to the intermediate redistribution layer 4, thereby realizing a heterogeneous junction between the upper dielectric layer 31 and the intermediate redistribution layer 4.

Each of the upper layer chips 33 has an upper redistribution layer 331 that is electrically connected to the intermediate redistribution layer 4, and upper active layer 332 stacked on and electrically connected to the upper redistribution layer 331, and an upper substrate 333 stacked on the active layer 332. Each of the upper layer chips 33 of the upper semiconductor module 3 has a thickness that ranges from 10 μm to 50 μm. It should be noted that the upper layer chips 33 are fabricated via a mature integrated circuit (IC) fabrication process. In the current terminology of the IC industry a mature IC fabrication process means the upper layer chips 33 are fabricated with a fabrication process above 7 nm. In this embodiment, the upper layer chips 33 consists of at least two chips selected from a group consisting of an I/O chip, a memory chip, a processor chip, and a passive chip.

It should be noted that the upper layer chips 33 of the upper semiconductor module 3, and the SoC processing chips 25 of the lower chip unit 24 of the lower semiconductor module 2 are bonded via a face-to face (F2F) process.

In this embodiment, the upper semiconductor module 3 further includes a top dielectric layer 5, and a dummy wafer 6. The top dielectric layer 5 has a thickness that ranges from 200 nm to 2000 nm, is connected to a surface of the upper dielectric layer 31 that is distant to said intermediate redistribution layer 4, is located below the dummy wafer 6, and located above the upper layer chips 33. The dummy wafer 6 is located above the upper dielectric layer 31 and is connected to the upper dielectric layer 31 via the top dielectric layer 5. The dummy wafer 6 provides additional structural strength and improves cooling in the 3D SoC.

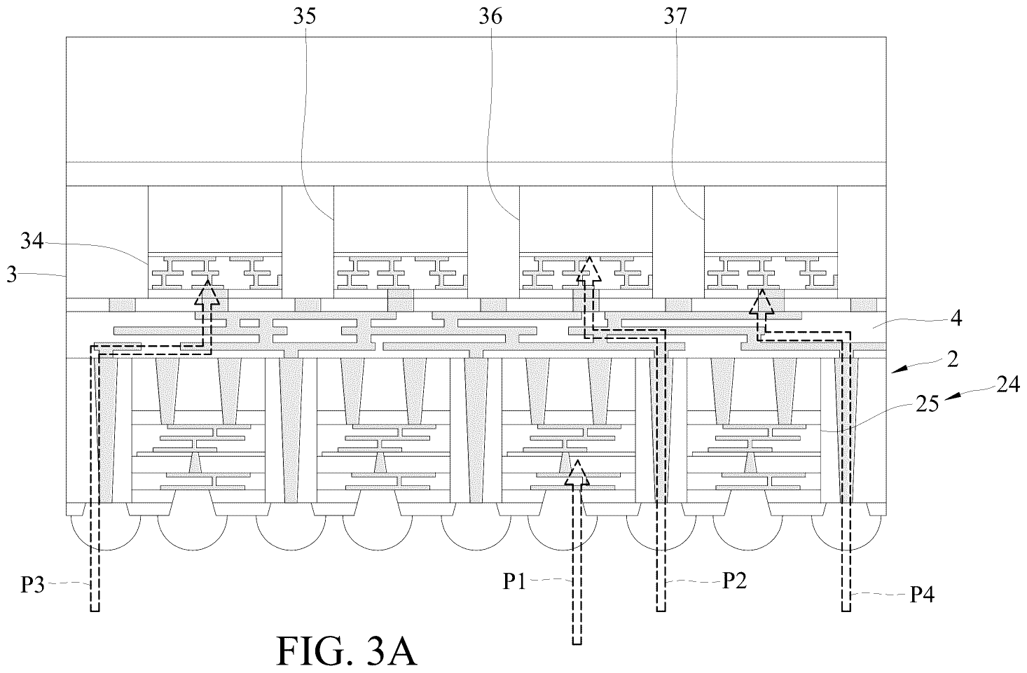

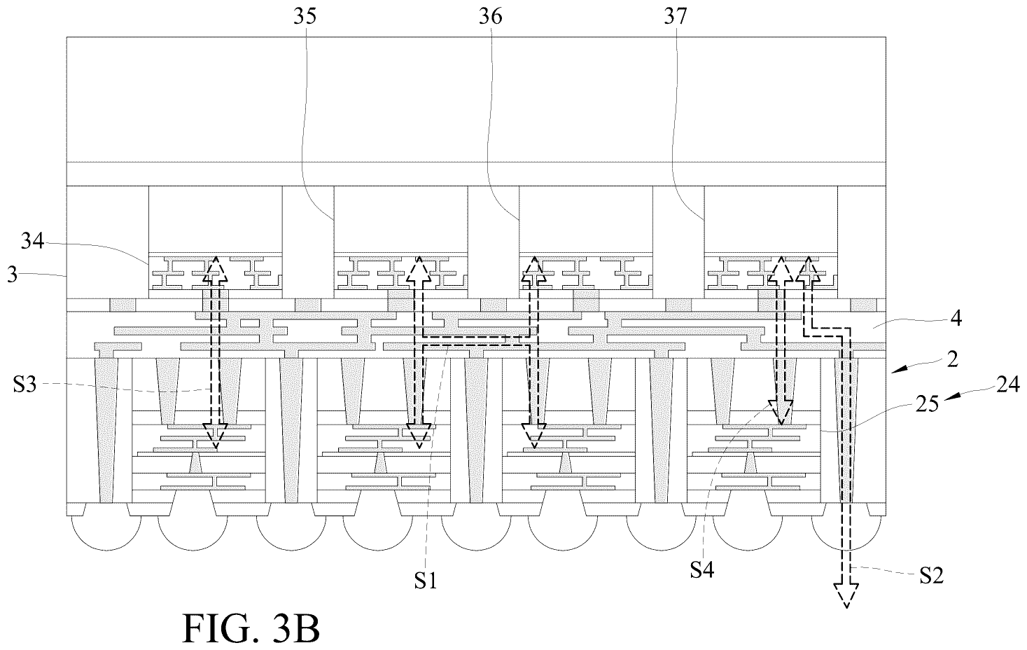

Referring to FIGS. 3A and 3B, FIG. 3A displays source voltage (Vss)/drain voltage (Vdd) connection pathways, while 3B displays signal connection pathways for the 3D SoC device. It is noted that in the FIGS. 3A and 3B, the upper layer chips 33 are, from left to right, an SRAM 34, a first processing chip 35 made with mature IC fabrication, a second processing chip 36 made with mature IC fabrication, and an I/O chip 37.

More specifically, FIG. 3A shows a first connection pathway (P1), a second connection pathway (P2), a third connection pathway (P3), and a fourth connection pathway (P4). The first connection pathway (P1) shows a back-side power delivery network (BSPDN) between one of the SoC processing chips 25 of the lower chip unit 24 of the lower semiconductor module 2 and the source voltage (Vss). The second connection pathway (P2) shows a front-side power delivery connection pathway between the second processing chip 36 (which is not a high-end processor) of the upper semiconductor module 3 and the source voltage (Vss). The third connection pathway (P3) shows a front-side power delivery connection pathway between the SRAM 34 and the source voltage (Vss). The fourth connection pathway (P4) shows a front-side power delivery connection pathway between the I/O chip 37 and the source voltage (Vss).

FIG. 3B shows a first signal connection pathway (S1), a second signal connection pathway (S2), a third signal connection pathway (S3), and a fourth signal connection pathway (S4). The first signal connection pathway (S1) shows signal connection paths of the first and second processing chips 35, 36 (which are not a high-end processor) of the upper semiconductor module 3 with the SoC processing chips 25 of the lower chip unit 24, signal connection paths in-between two of the SoC processing chips 25 of the lower chip unit 24, and connection paths in-between the first and second processing chips 35, 36 of the upper semiconductor module 3. The first signal connection pathway (S1) illustrates that the first and second processing chips 35, 36 cooperate with two of the SoC processing chips 25 of the lower chip unit 24 to complete computational tasks. The second signal connection pathway (S2) shows signal output paths from the 3D SoC device, or signal input paths to the 3D SoC device. The third signal connection pathway (S3) shows signal connection paths between one of the SoC processing chips 25 of the lower chip unit 24 of the lower semiconductor module 2 and the SRAM 34 of the upper semiconductor module 3. The fourth signal connection pathway (S4) shows signal connection paths between the I/O chip 37 of the upper semiconductor module 3 and one of the SoC processing chips 25 of the lower chip unit 24 of the lower semiconductor module 2.

Referring to FIGS. 3A and 3B, the 3D SoC device according to the present disclosure allocates the SoC processing chips 25, which requires greater signaling input/output, to the lower semiconductor module 2; the 3D SoC device is powered by a back-side power delivery network (BSPDN). This concentrates signaling input/output to the SoC processing chips 25 and decreases signal routing congestion and front-side overcrowding. For the upper layer chips 33 that are made with mature IC fabrication (in this embodiment including the SRAM 34, the first and second processing chips 35, 36, and the I/O chip 37) because the required signaling input/output is smaller relative to the SoC processing chips 25, they are collectively allocated to the upper semiconductor module 3 and powered by a front-side power delivery network (FSPDN) via the intermediate redistribution layer 4. This set up allows space in the lower semiconductor module 2 to be utilized efficiently to provide better processing power. It should be noted that in the case where the specifications of the SoC processing chips 25 of the lower semiconductor module 2 are changed (e.g., when the SoC processing chips 25 are to be upgraded to a newer specification), only the design of the photomask for the lower semiconductor module 2 will need to be changed, and the design of the photomask for the upper semiconductor module 3 may stay the same, thereby providing cost savings to the manufacturer.

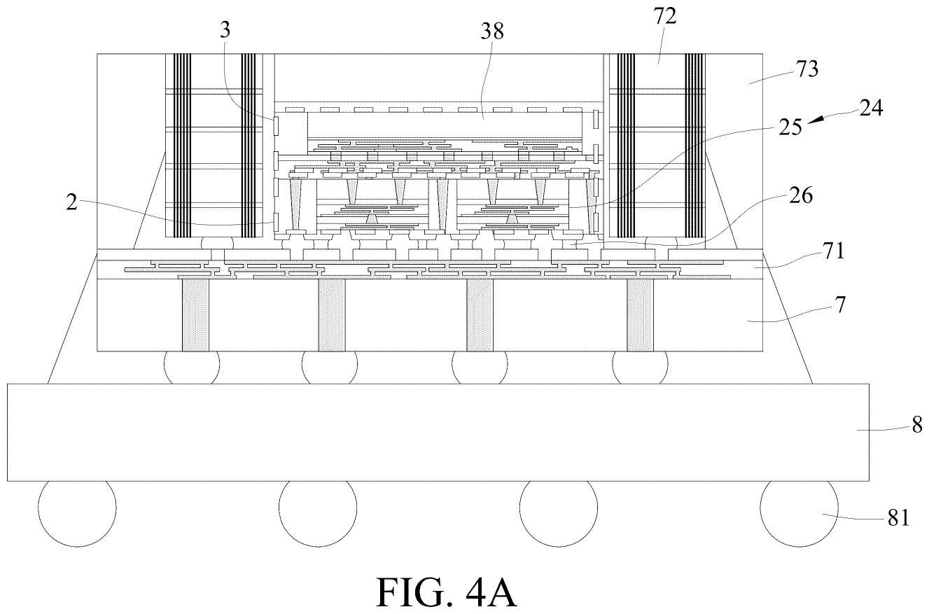

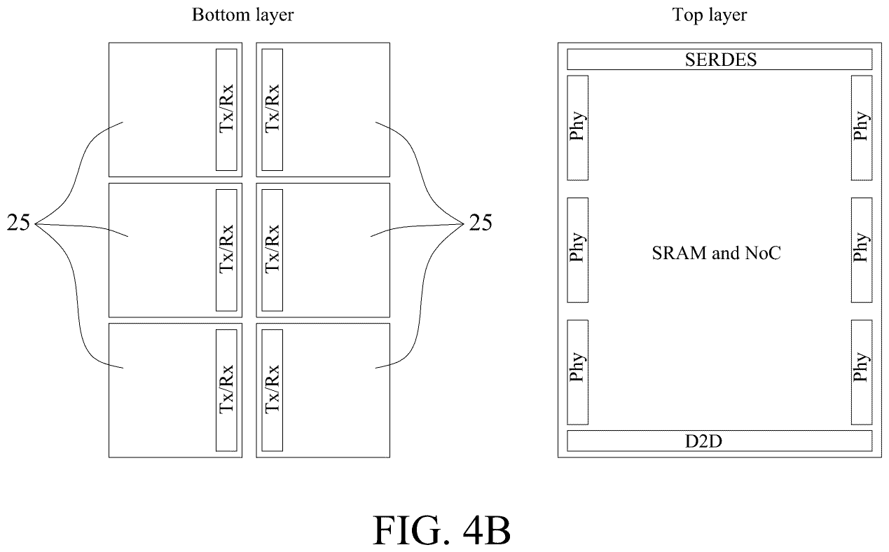

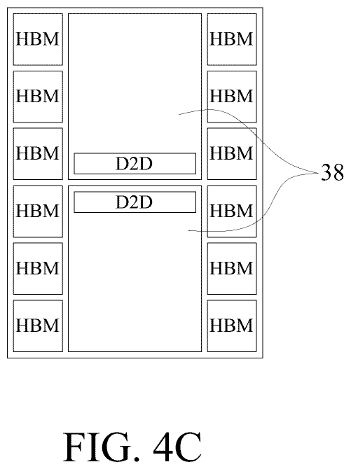

Referring to FIG. 4, FIG. 4 shows a second embodiment of the 3D SoC device. The second embodiment is different from the first embodiment in that the second embodiment is packaged in a 2.5D chip-on-wafer-on-substrate (CoWoS) packaging. In the second embodiment, the upper layer chips 33 in the upper semiconductor module 3 of the first embodiment are replaced by two integrated dies 38 (only one is shown in FIG. 4) that each include an I/O chip and a memory chip. More specifically, referring to FIG. 4C the upper semiconductor module 3 in the second embodiment includes two integrated dies 38 that are connected die to die (D2D). Referring to FIG. 4B, each of the two integrated dies 38 has a first side that is for D2D connection, a second side for connection to a serializer/deserializer (SERDES), and a third side that is disposed with a physical layer (Phy). In the second embodiment, there are six SoC processing chips 25 (only two are shown) in the lower chip unit 24 and they are arranged to be spaced apart in a 3×2 matrix. Referring to FIG. 4B, in the 3×2 matrix two SoC processing chips (25) from different columns are D2D connected for (Tx/Rx).

In addition to the above difference of the second embodiment, the 3D SoC processing device in the second embodiment includes an interposer substrate 7, an interposer redistribution layer 71, a plurality of high bandwidth memory (HBM) devices 72, an encapsulation layer 73, a ball grid array (BGA) unit 81, and a PCB 8. The interposer redistribution layer 71 is formed on the interposer substrate 7. The solder balls 26 are electrically connected to the interposer redistribution layer 71 on the interposer substrate 7. The HBM devices 72 are bonded to the redistribution layer 71. The encapsulation layer 73 encapsulates the HBM devices 72, the upper semiconductor module 3 and the lower semiconductor module 2 together in a single package. The interposer substrate 7 is bonded to the PCB 8 via the BGA unit 81.

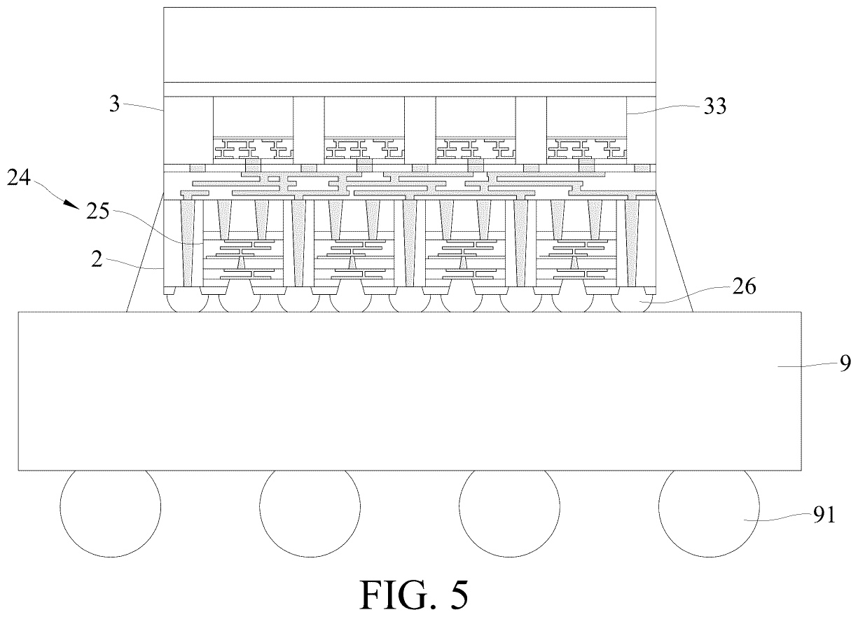

Referring to FIG. 5, a third embodiment of the 3D SoC device according to the present disclosure is generally similar to the first embodiment. However, the third embodiment is different from the first embodiment in having a BGA unit 91 and a PCB 9. In the third embodiment, the solder balls 26 are bonded to the PCB 9, and the BGA unit 91 is connected below the PCB 9.

In summary of the above, in the 3D SoC device according to the present disclosure, the lower chip unit 24 of the lower semiconductor module 2 includes only SoC processing chips 25 (high end processing chips). Therefore, space in the lower semiconductor module 2 need not be occupied by I/O chips, memory chips, or physical layers. Instead, all space in the lower semiconductor module may be exclusively used for SoC processing chips 25 (high end processing chips) which may improve space efficiency and computational power of the lower semiconductor module 2. Furthermore, the SoC processing chips 25 of the lower chip unit 24 of the lower semiconductor module 2 may be powered via BSPDN which lessens routing congestion, and may thereby allow the processing chips 25 to run with maximum computational performance.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A three-dimensional (3D) system-on-chip (SoC) device comprising:
An intermediate redistribution layer having a top surface and a bottom surface;
a lower semiconductor module located on said bottom surface of said intermediate redistribution layer; and
an upper semiconductor module located on said top surface of said intermediate redistribution layer;
wherein said intermediate redistribution layer electrically connects said lower semiconductor module to said upper semiconductor module and further connects to an external power source;
wherein said lower semiconductor module includes:
a lower dielectric layer that is located on said bottom surface of said intermediate redistribution layer;
a lower insulating layer that is located on a surface of said dielectric layer remote from said intermediate redistribution layer, and that includes a plurality of openings spaced apart from each other;
a plurality of lower conductive posts that pass through said lower dielectric layer, and that respectively correspond in position to some of said openings, each of said lower conductive posts having an end that is exposed from the corresponding one of said openings, and another end that is electrically connected with said intermediate redistribution layer; and
a lower chip unit composed of a plurality of SoC processing chips, and located in said lower dielectric layer, each of said SoC processing chips being located between adjacent ones of said lower conductive posts;
wherein each of said SoC processing chips includes:
a first processor redistribution layer which has a plurality of interconnects exposed from said openings;
a first processor substrate which is disposed on said first processor redistribution layer and which has a plurality of first vias formed through said first processor substrate;
a processor active layer formed on said first processor substrate and connected to said first processor redistribution layer through said first vias;
a second processor redistribution layer disposed on and electrically connected to said processor active layer;
a processor dielectric layer disposed on and connected to said second processor redistribution layer;
a second processor substrate disposed on and connected to said processor dielectric layer; and
a plurality of second vias which pass through said processor dielectric layer and said second processor substrate and each of which electrically connects with said second processor redistribution layer and said intermediate redistribution layer;
wherein said lower semiconductor module further includes a plurality of solder balls which are respectively disposed in said openings for electrical connection with said interconnects of said SoC processing chips and said lower conductive posts; and
wherein said upper semiconductor module includes:
an upper dielectric layer located on said upper surface of said intermediate redistribution layer;
a plurality of upper layer chips embedded in said upper dielectric layer in a spaced apart manner, each of said upper layer chips having an upper redistribution layer electrically connected to said intermediate redistribution layer, an upper active layer stacked on and electrically connected to said upper redistribution layer, and an upper substrate stacked on said upper active layer.

2. The 3D SoC device as claimed in claim 1, wherein said upper layer chips consists of at least two chips selected from a group consisting of an I/O chip, a memory chip, a processor chip, and a passive chip.

3. The 3D SoC device as claimed in claim 1, wherein each of said first vias in said first processor substrate of said lower semiconductor module has a diameter ranging from 100 nm to 500 nm.

4. The 3D SoC device as claimed in claim 1, wherein each of said SoC processing chips of said lower chip unit is fabricated with 7 nm /below technology.

5. The 3D SoC device as claimed in claim 1, wherein said first processor substrate of each of said SoC processing chips has a thickness that is less than 0.5 μm.

6. The 3D SoC device as claimed in claim 1, wherein each of said SoC processing chips of said lower chip unit has a thickness that ranges from 10 μm to 200 μm.

7. The SoC device as claimed in claim 1, wherein each of said solder balls of said lower semiconductor module has a thickness that ranges from 10 μm to 150 μm.

8. The SoC device as claimed in claim 1, wherein said solder balls are spaced apart from each other by a distance that ranges from 20 μm to 200 μm.

9. The 3D SoC device as claimed in claim 1, wherein, said upper semiconductor module further includes a dummy wafer located above said upper dielectric layers of said upper layer chips.

10. The 3D SoC device as claimed in claim 9, wherein said upper semiconductor module further includes a top dielectric layer disposed below said dummy wafer and above said upper layer chips.

11. The 3D SoC device as claimed in claim 10, wherein said top dielectric layer has a thickness that ranges from 200 nm to 2000 nm.

12. The 3D SoC device as claimed in claim 1, further comprising an interposer substrate and an interposer redistribution layer formed on said interposer substrate, said solder ball being electrically connected to said interposer redistribution layer on said interposer substrate.

13. The 3D SoC device as claimed in claim 1, further comprising a printed circuit board, said solder balls being electrically connected to said printed circuit board.

14. The 3D SoC device as claimed in claim 1, wherein each of said upper layer chips of said upper semiconductor module has a thickness that ranges from 10 μm to 50 μm.

15. The 3D SoC device as claimed in claim 1, wherein said lower chip unit has no memory chip and no I/O chip.

16. The 3D SoC device as claimed in claim 15, wherein:
said plurality of said SoC processing chips of said lower chip unit include six SoC processing chips arranged in a 3×2 matrix that has two columns and three rows; and
the SoC processing chips from different columns are D2D connected for (Tx/Rx).
